(19) United States
(12) Patent Application Publication
(10) Pub. No.: US 2008/0090402 A1
(43) Pub. Date: Apr. 17, 2008

(54) DENSIFYING SURFACE OF POROUS DIELECTRIC LAYER USING GAS CLUSTER ION BEAM

(76) Inventors: Griselda Bonilla, Fishkill, NY (US); Shyng-Tsong Chen, Rensselaer, NY (US); John A. Fitzsimmons, Poughkeepsie, NY (US); Sanjay Mehta, Niskayuna, NY (US); Shom Ponoth, Fishkill, NY (US)

Correspondence Address: HOFFMAN, WARNICK & D'ALESSANDRO LLC, 75 STATE ST, 14TH FL, ALBANY, NY, 12207, US

(21) Appl. No.: 11/536,893

(22) Filed: Sep. 29, 2006

(51) Int. Cl. H01L 21/44

(52) U.S. Cl. 438/599; 438/597

(57) ABSTRACT

A method of fabricating and a structure of an integrated circuit (IC) incorporating a porous dielectric layer are disclosed. A metal line is formed in the porous dielectric layer. A gas cluster ion beam process is applied to the porous dielectric layer so that an upper portion of the dielectric layer is densified to be not porous or non-interconnected low porous, while a lower portion of the porous dielectric layer still maintains its ultra-low dielectric constant after the gas cluster ion beam process.

### FIELD OF THE INVENTION

The invention relates generally to an integrated circuit (IC), and more particularly, to a method of fabricating and a structure of an IC incorporating a porous ultra-low K inter-layer dielectric layer with a surface densified using a gas cluster ion beam process.

### BACKGROUND ART

A dielectric constant (K) of an interlayer dielectric layer is known to have influences on the speed of interconnects. Ultra-low K materials are desirable to reduce capacitance between metal lines and increase the interconnect speed. Typically, by definition, materials having a K value no more than 2.5 are referred to as “ultra-low K” materials. Introducing nano-pores into dielectric materials is one of the methods to reduce the K value to the level of ultra-low K. The resulted dielectric materials are usually referred to as porous dielectric materials.

A back-end-of-the-line (BEOL) interconnect structure, e.g., metal lines 14 of FIG. 1, built in a porous ultra-low K (ULK) inter-layer dielectric layer (ILD) 12 usually need to have ULK ILD 12 exposed after a chemical mechanical planarization (CMP) process of metal lines 14. Usually, a subsequent cap layer 16 deposition requires a plasma pre-clean process to treat the metal surfaces of metal lines 14. This plasma pre-clean process can cause damage to low K dielectric materials, especially those with K values smaller than 2.8, such that the K values may increase significantly.

On the other hand, a BEOL structure without an extra protective hard mask layer (usually higher K material, not shown in the figure) between cap layer 16 and the underlying ULK ILD 12 between metal lines 14 may be susceptible to other problems, e.g., metal penetration into ULK ILD 12. As shown in FIG. 2, a misaligned via (i.e., a via contacting surface regions outside a metal line 14) 120 between a metal line 118 and metal line 14 may cause metal penetration 122 into ULK ILD layers 12 outside metal line 14 during a metallization process. A post reactive ion etching (RIE) wet clean may remove the ash damaged part of ULK ILD layer 12 directly under misaligned via 120 and may form an undercut below diffusion barrier layer 116. In addition, a commonly exercised directional liner etch back (usually referred to as an argon (Ar) sputter pre-clean) process (to remove natural oxide and post-etch residues from the bottom of vias 120 prior to a metal liner deposition) may also result in a significant punch-through into ULK ILD layer 12. As a consequence, metal penetration 122 outside metal line 14 may be formed during a metallization process. This metal extrusion between metal lines can cause reliability problems such as electrical leakage and/or early failure of time dependent dielectric breakdown.

The current state of the art technology does not provide a satisfactory solution to the above identified problems.

### SUMMARY OF THE INVENTION

A method of fabricating and a structure of an integrated circuit (IC) incorporating a porous dielectric layer are disclosed. A metal line is formed in the porous dielectric layer. A gas cluster ion beam process is applied to the porous dielectric layer so that an upper portion of the dielectric layer is densified to be not porous or non-interconnected low porous, while a lower portion of the porous dielectric layer still maintains its ultra-low dielectric constant after the gas cluster ion beam process.

An aspect of the present invention includes a method for fabricating an integrated circuit, the method comprising: providing a porous dielectric layer; forming a metal line in the porous dielectric layer, a surface of the metal line planar to a surface of the porous dielectric layer; and densifying an upper portion of the porous dielectric layer using a gas cluster ion beam process.

The illustrative aspects of the present invention are designed to solve the problems herein described and other problems not discussed which are discoverable by a skilled artisan.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a conventional semiconductor structure including an ultra-low K dielectric layer, metal lines and a cap layer.

FIG. 2 shows another conventional semiconductor structure including a metal penetration.

FIGS. 3-4 show one embodiment of a method of forming an integrated circuit incorporating a porous ultra-low K inter-layer dielectric layer with a densified surface, with FIG. 4 showing one embodiment of the integrated circuit, according to the invention.

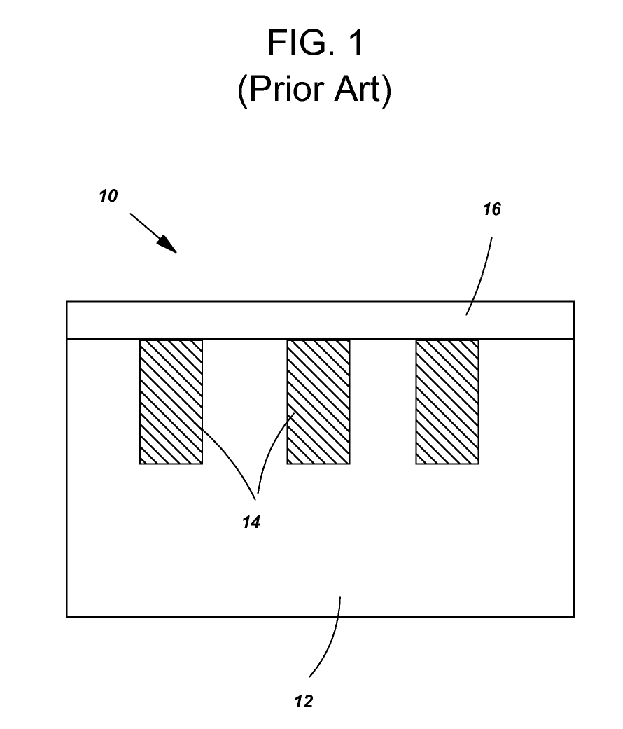

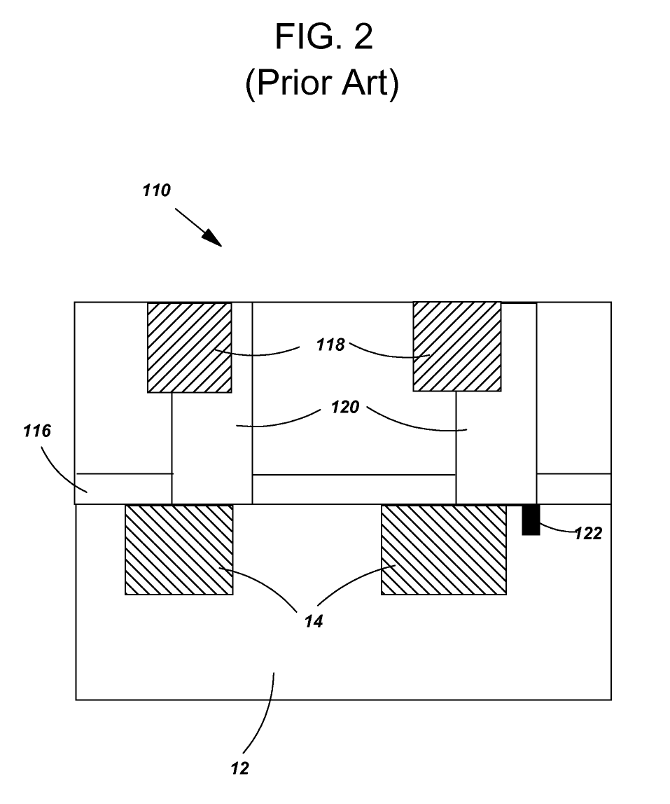

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

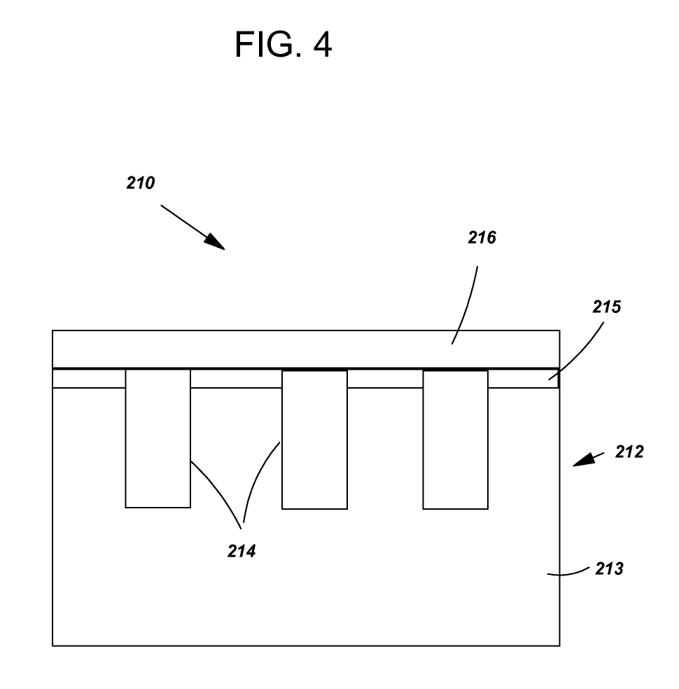

Referring to FIG. 4, one embodiment the invention includes an integrated circuit (IC) 210 having a porous inter-layer dielectric layer (dielectric layer) 212. Porous dielectric layer 212 includes an upper portion 215 atop a lower portion 213. According to one embodiment, upper portion 215 and lower portion 213 have different bulk properties, e.g., dielectric coefficient constant (K), with lower portion 213 including an ultra-low K material. It should be appreciated that any ultra-low K material now available or later developed may be used in lower portion 213 and all are included in the invention. Metal lines 214 are positioned in porous dielectric layer 212, with surfaces of metal lines 214 and the surface of porous dielectric layer 212 (specifically the surface of upper portion 215) planar to one another. Cap layer 216 is positioned over porous dielectric layer 212 and metal lines 214.

According to one embodiment, upper portion 215 is denser than lower portion 213 and is not porous, and has higher K value than lower portion 213. In addition, upper portion 215 is very thin relative to lower portion 213. According to one embodiment, the thickness of upper portion 215 is in the range of approximately 10 Å to approximately 500 Å, with a preferred range of approximately 100 Å to approximately 200 Å. As such, porous dielectric layer 212 may be referred to as a porous ultra-low K (ULK) inter-layer dielectric (ILD) layer with a densified surface.

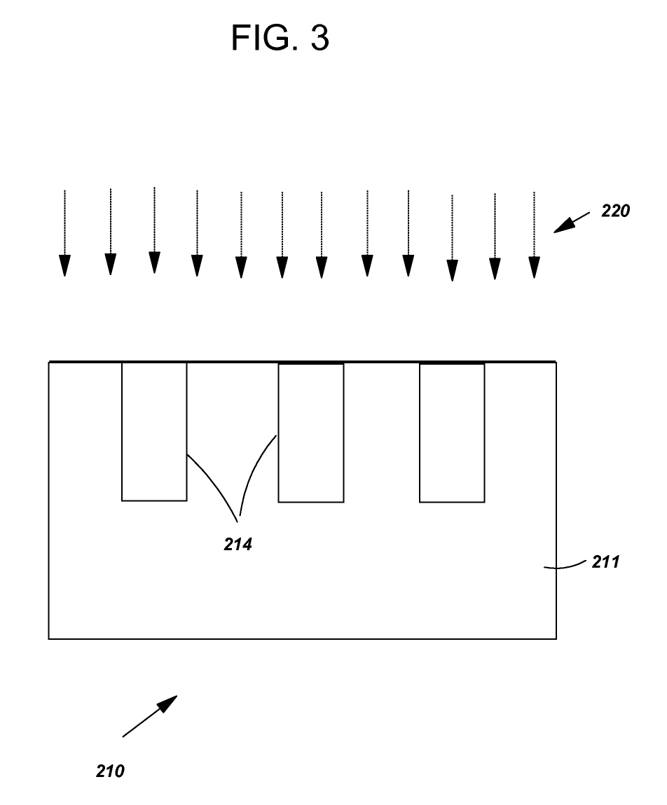

FIGS. 3-4 show one embodiment of forming IC 210 (FIG. 4). Referring to FIG. 3, a porous dielectric layer 211 is deposited/provided using any methods, e.g., CVD, PVD or spin-on method. Porous dielectric layer 211 includes an ultra-low K material. According one embodiment, porous dielectric layer 211 may have a K value in the range of approximately 1.5 to approximately 2.5, with a preferred range from approximately 2.0 to approximately 2.4, and an average pore size in the range of approximately 0.1 nm to approximately 4 nm, with a preferred range of approximately 0.5 nm to approximately 1.5 nm, with the understanding that the above parameters do not limit the scope of the current invention. Next, metal lines 214, e.g., of copper (Cu), are formed in porous dielectric layer 211 using any method, e.g., photolithography, patterning, etching, etc. Next, a metal chemical mechanical polishing (CMP) process is conducted so that surfaces of metal lines 214 and surface of porous dielectric layer 211 are planar to one another.

Referring to FIG. 3, a gas cluster ion beam (GCIB) process 220 is applied to porous dielectric layer 211 to densify an upper portion (or surface) of porous dielectric layer 211 to produce a densified non-porous or non-interconnected low porous upper portion 215. The material and parameters/conditions of the GCIB process need to be controlled so that the bulk property, e.g., dielectric constant, of most of porous dielectric layer 211 is unchanged. GCIB process 220 may use at least one of Oxygen (O₂), Nitrogen (N2), Argon (Ar), Neon (Ne), Krypton (Kr), Xenon (Xe) gases, and may uses an energy level in the range of approximately 1 KeV to approximately 60 keV, with a preferred range of approximately 5 KeV to approximately 15 keV.

According to one embodiment, using an Oxygen (O₂) beam and an energy level of approximately 10 KeV in the GCIB process may obtain a very thin (˜100 Å) and non-porous upper portion 215. However, it should be appreciated that other embodiments are also included in the invention. Since the ion cluster size is larger than the pore size of the ULK materials of porous dielectric layer 211 (FIG. 3), after the GCIB process, lower portion 213 (FIG. 4) of porous dielectric layer 211 (FIG. 3) maintains the original bulk property, e.g., dielectric constant, of porous dielectric layer 211, which is different than that of non-porous densified upper portion 215 (FIG. 4). After the GCIB, as shown in FIG. 4, upper portion 215 and lower portion 213 are collectively referred to porous dielectric layer 212 to differentiate from the original porous dielectric layer 211 (FIG. 3). Following the GCIB process, a plasma pre-clean process may be applied to treat surfaces of metal lines 214, and cap layer 216 may be deposited over porous dielectric layer 212 and metal lines 214 without damaging the ULK material of lower portion 213 under densified surface/upper portion 215.

The structures described above are used in integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method for fabricating an integrated circuit, the method comprising:
providing a porous dielectric layer;
forming a metal line in the porous dielectric layer, a surface of the metal line planar to a surface of the porous dielectric layer; and
densifying an upper portion of the porous dielectric layer using a gas cluster ion beam process.

2. The method of claim 1, wherein the gas cluster ion beam process uses at least one of Oxygen (O₂), Nitrogen (N2), Argon (Ar), Neon (Ne), Krypton (Kr), Xenon (Xe) gases.

3. The method of claim 1, wherein the gas cluster ion beam process uses an energy level in the range of 1 to 60 keV.

4. The method of claim 3, wherein the gas cluster ion beam process uses an energy level in range of 5 to 15 keV.

5. The method of claim 1, wherein the porous dielectric layer includes ultra-low dielectric constant material.

6. The method of claim 5, wherein a lower portion of the porous dielectric layer maintains an original dielectric constant thereof after the gas cluster ion beam process.

7. The method of claim 1, further including applying a plasma pre-clean process to treat the surface of the metal line.

8. The method of claim 7, further including depositing a cap layer over the porous dielectric layer and the metal line.
